(19) United States
(12) Patent Application Publication
(10) Pub. No.: US 2026/0070150 A1
(43) Pub. Date: Mar. 12, 2026

(54) APPARATUS AND METHOD FOR MANUFACTURING DISPLAY APPARATUS, AND METHOD FOR MANUFACTURING ELECTRONIC DEVICE

(71) Applicant: Samsung Display Co., LTD., Yongin-si (KR)

(72) Inventors: Woongil Choi, Yongin-si (KR); Jinsung Kang, Yongin-si (KR); Seunggil Yoo, Yongin-si (KR); Changhyuk Jeong, Yongin-si (KR); Hyunho Choi, Yongin-si (KR)

(21) Appl. No.: 19/257,832

(22) Filed: Jul. 2, 2025

(30) Foreign Application Priority Data
Sep. 9, 2024 (KR) 10-2024-0122647

(51) Int. Cl. B23K 26/035; B23K 26/06; B23K 26/08; B23K 101/36; H10H 29/01; H10K 59/12; H10K 71/00

(52) U.S. Cl. CPC B23K 26/035; B23K 26/0643; B23K 26/0648; B23K 26/0869; H10H 29/012; H10K 59/1201; H10K 71/861; B23K 2101/36

(57) ABSTRACT

An apparatus includes a stage on which a display substrate is disposed, a light source unit that generates light and irradiates a laser beam in a first direction, and an optical path module that reflects the laser beam irradiated and input from the light source unit, outputs the laser beam in a second direction crossing the first direction, and irradiates the laser beam on the stage. The optical path module includes a head unit including an input opening through which the laser beam is input, a level adjustment unit disposed under the head unit and being capable of adjusting a level of the head unit in a height direction, a position adjustment unit disposed under the level adjustment unit and being capable of adjusting a position of the head unit in a longitudinal direction, and a base disposed under the position adjustment unit.

This application claims priority to Korean Patent Application No. 10-2024-0122647, filed on Sep. 9, 2024, and all the benefits accruing therefrom under 35 U.S.C. § 119, the content of which in its entirety is herein incorporated by reference.

### BACKGROUND

### 1. Field

Embodiments relate to an apparatus and a method and, more specifically, to an apparatus and method for manufacturing a display apparatus, and method for manufacturing an electronic device.

### 2. Description of the Related Art

Electronic devices are being widely used. Electronic devices are used in various ways, for example as mobile electronic devices and stationary electronic devices. Electronic devices include display apparatuses capable of providing users with visual information, such as images or videos, to support various functions.

During manufacturing of a display apparatus, various foreign substances cause defects that prevent pixels from being turned on/off, and when such defects occur, the display apparatus is treated as defective and should be discarded, resulting in an increase in manufacturing costs. In order to reduce manufacturing costs and defect rates, a repair process to repair defects is essentially included in a manufacturing process.

In this repair process, a repair process using a laser may be used. Precise control is desired to irradiate a laser beam to a display apparatus. At this time, precisely controlling and standardizing input and output positions of a laser beam are desired.

### SUMMARY

Embodiments include an apparatus and method for manufacturing a display apparatus and method for manufacturing an electronic device, where the apparatus may allow precise control and standardization of input and output positions of a laser beam.

However, such an objective is exemplary, and the objective of the disclosure is not limited thereby.

Additional features will be set forth in part in the description which follows and, in part, will be apparent from the description, or may be learned by practice of the presented embodiments of the disclosure.

In an embodiment of the disclosure, an apparatus for manufacturing a display apparatus includes a stage on which a display substrate is disposed, a light source unit that generates light and irradiates a laser beam in a first direction, and an optical path module that reflects the laser beam irradiated and input from the light source unit, outputs the laser beam in a second direction crossing the first direction, and irradiates the laser beam on the stage. The optical path module includes a head unit defining an input opening through which the laser beam is input, a level adjustment unit disposed under the head unit and being capable of adjusting a level of the head unit in a height direction, a position adjustment unit disposed under the level adjustment unit and being capable of adjusting a position of the head unit in a longitudinal direction, and a base disposed under the position adjustment unit.

In an embodiment, the optical path module may further include a grid plate disposed to cover the input opening in the head unit and including grid lines.

In an embodiment, the optical path module may further include a guide rail disposed on one surface of the head unit and defining a groove to allow the grid plate to slide and be detachable therefrom.

In an embodiment, the grid plate may include an alignment protrusion protruding from a bottom portion thereof, and the alignment protrusion may be coupled to an alignment recess provided in the level adjustment unit.

In an embodiment, the level adjustment unit may include a first plate and first and second bolts inserted into the first plate. The first bolt may be fastened to a threaded hole of the position adjustment unit, and the second bolt may not be fastened to the position adjustment unit.

In an embodiment, the first bolt may lower the first plate as the first bolt is tightened, and the second bolt may raise the first plate as the second bolt is tightened.

In an embodiment, the second bolt may contact a top surface of the position adjustment unit.

In an embodiment, the second bolt may include a rounded end screw.

In an embodiment, the first bolt may be disposed further inside the first plate than the second bolt.

In an embodiment, the level adjustment unit may further include a horizontal measurement unit that is disposed on the first plate and measures a degree of horizontality of the first plate.

In an embodiment, the horizontal measurement unit may be disposed on each edge along a perimeter of the first plate.

In an embodiment, the position adjustment unit may include a second plate that is movable in the longitudinal direction, and a third bolt inserted into the second plate. The second plate may define an extension hole through which the third bolt is inserted.

In an embodiment, the extension hole may be an opening extending in the longitudinal direction such that the third bolt is disposed in the extension hole when the second plate moves in the longitudinal direction.

In an embodiment, the position adjustment unit may further include a position measurement unit that is disposed on one side of the second plate in the longitudinal direction and measures a degree of movement of the second plate in the longitudinal direction.

In an embodiment, the position adjustment unit may further include a protrusion protruding from a bottom portion of the second plate toward the base and extending in the longitudinal direction, the base may define a receiving groove extending in the longitudinal direction to accommodate the protrusion, and the protrusion may be slidable along the receiving groove.

In an embodiment, the apparatus may further include a detachable target plate on one side of the stage. The target plate may include a target mark on a top surface thereof to indicate a position where the output laser beam is irradiated.

In an embodiment, the target plate may further include a protruding shaft protruding from a bottom portion thereof, the stage may further define a mounting hole provided at a position corresponding to the protruding shaft, and the protruding shaft may be fitted into the mounting hole.

In an embodiment, the apparatus may further include an optical unit disposed between the light source unit and the optical path module and including a plurality of lenses.

In an embodiment, the apparatus may further include a support plate that supports the light source unit and the optical path module and is spaced apart from and faces the stage.

In an embodiment of the disclosure, a method of manufacturing a display apparatus includes arranging a display substrate on a stage, irradiating a laser beam in a first direction by generating light from a light source unit, and repairing the display substrate by reflecting the laser beam irradiated and input from the light source unit, outputting the laser beam in a second direction crossing the first direction, and irradiating the laser beam on the display substrate. The optical path module includes a head unit defining an input opening through which the laser beam is input, a level adjustment unit disposed under the head unit and being capable of adjusting a level of the head unit in a height direction, a position adjustment unit disposed under the level adjustment unit and being capable of adjusting a position of the head unit in a longitudinal direction, and a base disposed under the position adjustment unit.

In an embodiment of the disclosure, a method of manufacturing a electronic device includes arranging a display substrate on a stage, irradiating a laser beam in a first direction by generating light from a light source unit, and repairing the display substrate by reflecting the laser beam irradiated and input from the light source unit, outputting the laser beam in a second direction crossing the first direction, and irradiating the laser beam on the display substrate. The optical path module includes a head unit defining an input opening through which the laser beam is input, a level adjustment unit disposed under the head unit and being capable of adjusting a level of the head unit in a height direction, a position adjustment unit disposed under the level adjustment unit and being capable of adjusting a position of the head unit in a longitudinal direction, and a base disposed under the position adjustment unit.

Other features and advantages than those described above will become apparent from the following drawings, claims, and detailed descriptions to embody the disclosure below.

### BRIEF DESCRIPTION OF THE DRAWINGS

The above and other features and advantages of illustrative embodiments of the disclosure will be more apparent from the following description taken in conjunction with the accompanying drawings, in which:

FIG. 1 is a diagram schematically showing an embodiment of an apparatus for manufacturing a display apparatus;

FIG. 2 is a perspective view schematically showing an embodiment of an optical path module;

FIG. 3 is a cross-sectional view schematically showing an embodiment of a portion of a level adjustment unit, and may correspond to a cross-section taken along line III-III′ of FIG. 2;

FIG. 4 is a perspective view schematically showing an embodiment of a stage;

FIG. 5 is a plan view schematically showing an embodiment of a display apparatus manufactured using an apparatus for manufacturing a display apparatus; and

FIG. 6 is a cross-sectional view schematically showing an embodiment of a display apparatus manufactured using an apparatus for manufacturing a display apparatus, and may correspond to a cross-section of the display apparatus taken along line VI-VI′ of FIG. 5.

### DETAILED DESCRIPTION

Reference will now be made in detail to embodiments, embodiments of which are illustrated in the accompanying drawings, where like reference numerals refer to like elements throughout the specification. In this regard, the illustrated embodiments may have different forms and should not be construed as being limited to the descriptions set forth herein. Accordingly, the embodiments are merely described below, by referring to the drawing figures, to explain features of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Various modifications may be applied to the illustrated embodiments, and particular embodiments will be illustrated in the drawings and described in the detailed description section. The effect and features of the disclosure, and a method to achieve the same, will be clearer referring to the detailed descriptions below with the drawings. However, the illustrated embodiments may be implemented in various forms, not by being limited to the embodiments presented below.

Hereinafter, embodiments of the disclosure will be described in detail with reference to the accompanying drawings, and in the description with reference to the drawings, the same or corresponding components are indicated by the same reference numerals and redundant descriptions thereof are omitted.

In the following embodiment, it will be understood that although the terms “first,” “second,” etc. may be used herein to describe various components, these components should not be limited by these terms. These terms are only used to distinguish one component from another.

In the following embodiment, the expression of singularity in the specification includes the expression of plurality unless clearly specified otherwise in context.

In the following embodiment, it will be further understood that the terms “comprises” and/or “comprising” used herein specify the presence of stated features or components, but do not preclude the presence or addition of one or more other features or components.

In the following embodiment, it will be understood that when a layer, region, or component is referred to as being “formed on” another layer, region, or component, it may be directly or indirectly formed on the other layer, region, or component. That is, for example, intervening layers, regions, or components may be present.

It will be understood that when a layer, region, or component is referred to as being “connected to” another layer, area, or component, it may be directly or indirectly connected to the other layer, region, or component. That is, for example, intervening layers, regions, or components may be present. It will be understood that when a layer, region, or component is referred to as being electrically connected to another layer, area, or component, it may be directly or indirectly electrically connected to the other layer, region, or component. That is, for example, intervening layers, regions, or components may be present.

Sizes of components in the drawings may be exaggerated or reduced for convenience of explanation. In other words, since sizes and thicknesses of components in the drawings are arbitrarily illustrated for convenience of explanation, the following the disclosure is not limited thereto.

In the following embodiment, the expression “A and/or B” represents A, B, or A and B. In addition, the expression “at least any one of A and B”represents A, B, or A and B.

In the following embodiment, when a wire “extends in a first direction or a second direction,” it may not only mean that the wire extends in a straight line, but may also mean that the wire extends in a zigzag or curved line in the first direction or the second direction.

In the following embodiment, the expression “in a plan view” refers to when a target portion is viewed from above. In the following embodiment, the expression “in a cross-section” refers to a side view of a vertically cut cross-section of a target portion. In the following embodiment, when a first component “overlaps” a second component, it means that the first component is disposed above or under the second component.

In the following embodiment, the x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When an illustrative embodiment may be implemented differently, a predetermined process order may be performed differently from the described order. For example, two consecutively described processes may be performed substantially at the same time or performed in an order opposite to the described order.

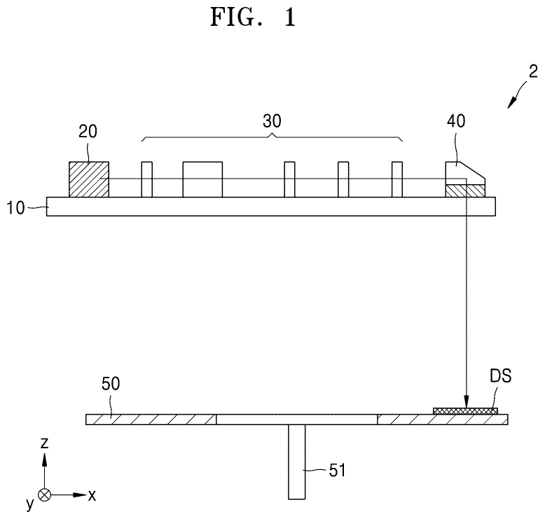

FIG. 1 is a diagram schematically showing an embodiment of an apparatus for manufacturing a display apparatus.

Referring to FIG. 1, in an embodiment, an apparatus 2 for manufacturing a display apparatus may include a support plate 10, a light source unit 20, an optical unit 30, an optical path module 40, and a stage 50.

The support plate 10 may support the light source unit 20, the optical unit 30, and the optical path module 40. In an embodiment, the light source unit 20, the optical unit 30, and the optical path module 40 may be disposed (e.g., seated) on the support plate 10, and the support plate 10 may be disposed above the stage 50 such that the support plate 10 is spaced apart from and faces the stage 50. Although not shown in the drawing, the support plate 10 may be connected to a gantry and may move forward and backward in a first direction (x direction).

As a laser source, the light source unit 20 may emit a laser beam, e.g., an excimer laser beam. In another embodiment, the light source unit 20 may emit a linearly polarized laser beam. The light source unit 20 may include the concept of a conventional laser source and a linear polarizing plate. The light source unit 20 may use a fiber laser, and the fiber laser has advantages of being capable of output control over a wide range, having relatively low maintenance costs, and being highly efficient, for example. Hereinafter, for convenience of explanation, a case where the light source unit 20 irradiates a laser beam in the first direction (x direction) is mainly described.

The optical unit 30 may include a plurality of lens. The optical unit 30 may include a cylindrical or spherical lens. In an embodiment, the optical unit 30 may reduce or enlarge the size of a laser beam in the first direction (x direction) and/or a third direction (y direction). In addition, in an embodiment, the optical unit 30 may include a beam splitter and/or an optical rotation unit.

The optical path module 40 may change a path of the laser beam input from the light source unit 20. In an embodiment, the optical path module 40 may reflect a laser beam incident in the first direction (x direction) and output the laser beam in a second direction (z direction), for example. At this time, the laser beam directed to the optical path module 40 may be defined as an input laser beam. In addition, the laser beam emitted from the optical path module 40 may be defined as an output laser beam. The optical path module 40 may include a reflective mirror (not shown) to change a path of the input laser beam. The output laser beam from the optical path module 40 may be irradiated toward the stage 50.

The stage 50 may support a display substrate DS. In other words, the display substrate DS may be brought in and disposed (e.g., seated) on the stage 50. The output laser beam from the optical path module 40 may be irradiated onto the display substrate DS on the stage 50, and may repair a portion, e.g., a pixel, of the display substrate DS. In an embodiment, a rotation drive unit 51 may be disposed under the stage 50. The rotation drive unit 51 may rotate the stage 50, with the rotation drive unit 51 acting as a rotation axis. Accordingly, after the display substrate DS is brought in on one side of the stage 50, the stage 50 may rotate to position the display substrate DS on an opposite side, with the rotation drive unit 51 acting as a rotation axis. Next, the support plate 10 may move in the first direction (x direction), allowing a laser beam to be irradiated toward the display substrate DS.

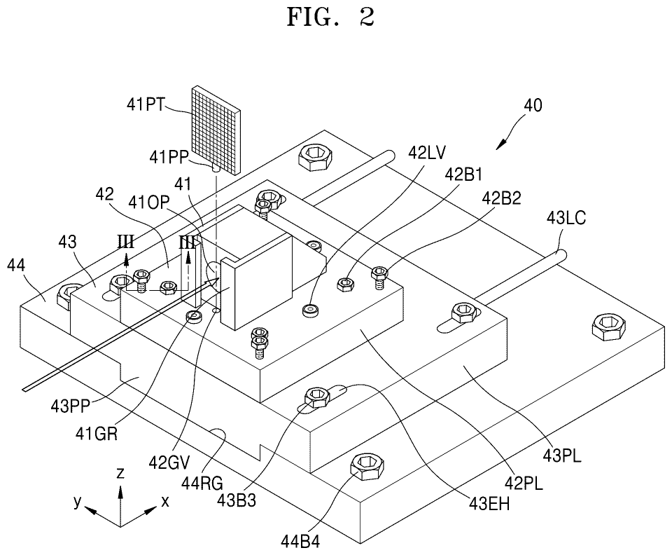

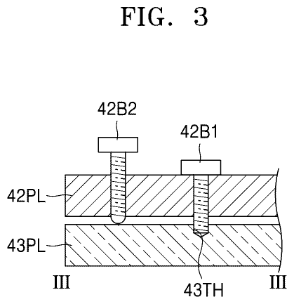

FIG. 2 is a perspective view schematically showing an embodiment of an optical path module. FIG. 3 is a cross-sectional view schematically showing an embodiment of a portion of a level adjustment unit, and may correspond to a cross-section taken along line III-III′ of FIG. 2.

Referring to FIG. 2, in an embodiment, the optical path module 40 may include a head unit 41, a level adjustment unit 42, a position adjustment unit 43, and a base 44.

A laser beam irradiated from the light source unit 20 may be input to the head unit 41. In an embodiment, a laser beam may be irradiated from the light source unit 20 in the first direction, and at this time, the head unit 41 may be spaced apart from the light source unit 20 in the first direction (x direction), for example.

The head unit 41 may define an input opening 410P through which a laser beam is input. The input opening 410P may be defined in a front surface of the head unit 41. In an embodiment, the input opening 410P may be provided to have a circular shape, but is not necessarily limited thereto, and may be provided to have a polygonal shape such as a quadrangular shape.

A laser beam input through the input opening 410P may be reflected by the reflective mirror (not shown) disposed in the head unit 41, and thus, a path of the laser beam may be changed. The reflective mirror may reflect a laser beam input in the first direction and output the laser beam in the second direction (z direction) crossing the first direction. At this time, the reflective mirror may be disposed at an angle with respect to the first direction.

In an embodiment, a grid plate 41PT may be disposed on one surface, e.g., the front surface, of the head unit 41. The grid plate 41PT may be disposed on the front surface of the head unit 41 to cover the input opening 410P. A laser beam may pass through the grid plate 41PT. In an embodiment, the grid plate 41PT may be provided with grid lines. The grid lines have predetermined intervals, e.g., in millimeter (mm) units, and may be used as graduations. Accordingly, an input position of a laser beam may be marked on the grid plate 41PT, and precise control of the input position of the laser beam may be facilitated.

In addition, in an embodiment, in order to mount the grid plate 41PT on the front surface of the head unit 41, a guide rail 41GR may be disposed on the front surface of the head unit 41. In an embodiment, the guide rail 41GR may be disposed at opposite sides of the front surface of the head unit 41 and may extend vertically, for example. The guide rail 41GR may define a groove, allowing the grid plate 41PT to be accommodated in the groove. The grid plate 41PT may be inserted into the groove in the guide rail 41GR and may vertically slide, and thus may be easily detached therefrom. Because the grid plate 41PT may be easily detached, maintenance of the apparatus 2 for manufacturing a display apparatus may be facilitated.

In an embodiment, the grid plate 41PT may include an alignment protrusion 41PP protruding from a bottom portion thereof. In an embodiment, the alignment protrusion 41PP may protrude from the center of a bottom edge of the grid plate 41PT, for example. In the drawing, it is shown that one alignment protrusion 41PP is disposed at the center of the bottom edge of the grid plate 41PT, but the disclosure is not limited thereto. In another embodiment, the alignment protrusion 41PP include a plurality of alignment protrusions 41PP, and the plurality of alignment protrusions 41PP may be spaced apart from each other at the bottom edge of the grid plate 41PT. Hereinafter, for convenience of explanation, a case where one alignment protrusion 41PP is provided is mainly described.

The alignment protrusion 41PP may be inserted and fitted into an alignment recess 42GV provided in the level adjustment unit 42. Accordingly, the grid plate 41PT may be disposed in alignment with the head unit 41 and the level adjustment unit 42. In addition, the grid plate 41PT may be fixed by coupling the alignment protrusion 41PP with the alignment recess 42GV.

The level adjustment unit 42 may adjust the level of the head unit 41. At this time, the level may refer to a position in a height direction, e.g., the second direction (z direction). The level adjustment unit 42 may be disposed under the head unit 41. In an embodiment, the level adjustment unit 42 may include a first plate 42PL, a first bolt 42B1, a second bolt 42B2, and a horizontal measurement unit 42LV.

The first plate 42PL may be disposed under the head unit 41 to support the head unit 41. The first plate 42PL may be larger than the head unit 41 in a plan view. In an embodiment, the first plate 42PL may have a quadrangular shape, but the disclosure is not limited thereto. In another embodiment, the first plate 42PL may have a circular shape or another polygonal shape. Hereinafter, a case where the first plate 42PL has a quadrangular shape is mainly described.

Referring additionally to FIG. 3, the first bolt 42B1 and the second bolt 42B2 may adjust the level of the head unit 41 disposed (e.g., seated) on the first plate 42PL, by adjusting the level of the first plate 42PL. In an embodiment, the first bolt 42B1 may be a pull bolt, and the second bolt 42B2 may be a push bolt.

In an embodiment, the first bolt 42B1 may include a plurality of first bolts 42B1, and the first bolts 42B1 may be arranged around the perimeter of the first plate 42PL. In a plan view, the first bolts 42B1 may be arranged next (adjacent) to each corner of the first plate 42PL. The second bolt 42B2 may also include a plurality of second bolts 42B2, and the second bolts 42B2 may be arranged around the perimeter of the first plate 42PL. In a plan view, the second bolts 42B2 may be arranged next (adjacent) to each corner of the first plate 42PL. At this time, the first bolts 42B1 may be arranged further inside the first plate 42PL than the second bolts 42B2. When the first bolt 42B1 is disposed further inside the first plate 42PL than the second bolt 42B2, it means that the first bolt 42B1 is disposed closer to the center of the first plate 42PL than is the second bolt 42B2. In other words, the first bolt 42B1 and the second bolt 42B2 may be arranged in order from the center of the first plate 42PL toward a corner of the first plate 42PL.

The first bolt 42B1 is a pull bolt and may be disposed to be inserted into the first plate 42PL. In addition, the first bolt 42B1 may be threaded and fastened to a second plate 43PL of the position adjustment unit 43 disposed under the first plate 42PL. In other words, the second plate 43PL may define a threaded hole 43TH corresponding to the first bolt 42B1, and the first bolt 42B1 may be inserted and fastened into the threaded hole 43TH. Accordingly, as the first bolt 42B1 is tightened, the level of the first plate 42PL may be lowered.

The second bolt 42B2 is a push bolt and may be disposed to be inserted into the first plate 42PL. In addition, the second bolt 42B2 may not be fastened to the second plate 43PL of the position adjustment unit 43 disposed under the first plate 42PL. In other words, the second bolt 42B2 may be disposed in contact with a top surface of the second plate 43PL. Accordingly, as the second bolt 42B2 is tightened, the second bolt 42B2 may raise the level of the first plate 42PL. As such, the level adjustment unit 42 may raise and lower the level of the first plate 42PL through the first bolt 42B1 and the second bolt 42B2, which are arranged along the perimeter of the first plate 42PL. In addition, as the level of the head unit 41 disposed (e.g., seated) on the first plate 42PL is also adjusted, an input position of a laser beam may be controlled more precisely.

In addition, in an embodiment, the second bolt 42B2 may include a rounded end screw. In other words, an end portion of the second bolt 42B2, which contacts the top surface of the second plate 43PL, may have a rounded protruding shape. This ensures that a constant point of contact with the second plate 43PL is always maintained even as a screw rotates when tightened. Accordingly, the level of the first plate 42PL may be adjusted more finely.

The horizontal measurement unit 42LV may ensure that the level adjustment unit 42 is disposed horizontally. In an embodiment, the horizontal measurement unit 42LV may include a level. The horizontal measurement unit 42LV may be used to measure and verify the horizontal condition of the first plate 42PL, and the level of the first plate 42PL may be adjusted accordingly. The horizontal measurement unit 42LV may include at least one horizontal measurement unit 42LV, and the at least one horizontal measurement unit 42LV may be disposed next (adjacent) to at least one edge of the first plate 42PL. In an embodiment, the horizontal measurement unit 42LV may include four horizontal measurement units 42LV, and these four horizontal measurement units 42LV may be arranged next (adjacent) to four edges of the first plate 42PL, respectively, for example. In other words, each of horizontal measurement units 42LV may be disposed between two neighboring (adjacent) first bolts 42B1. In addition, each of the horizontal measurement units 42LV may be arranged between two neighboring (adjacent) second bolts 42B2.

The position adjustment unit 43 may adjust the position of the head unit 41. In detail, the position adjustment unit 43 may adjust the position of the head unit 41 in a longitudinal direction, e.g., the first direction (x direction). In an embodiment, the position adjustment unit 43 may include the second plate 43PL, a third bolt 43B3, and a position measurement unit 43LC.

The second plate 43PL may be disposed under the level adjustment unit 42, e.g., the first plate 42PL, to support the level adjustment unit 42. The second plate 43PL may be larger than the first plate 42PL in a plan view. In an embodiment, the second plate 43PL may have a quadrangular shape, but the disclosure is not limited thereto. In another embodiment, the second plate 43PL may have a circular shape or another polygonal shape. Hereinafter, a case where the second plate 43PL has a quadrangular shape is mainly described.

In an embodiment, the second plate 43PL may include a protrusion 43PP protruding from a bottom portion of the second plate 43PL. The protrusion 43PP may protrude from a bottom surface of the second plate 43PL toward the base 44 disposed under the second plate 43PL. In addition, the protrusion 43PP may extend in the longitudinal direction, e.g., the first direction (x direction) from the bottom surface of the second plate 43PL along a center of its width, e.g., a center of the length in the third direction (y direction). At this time, the protrusion 43PP may be accommodated in a receiving groove 44RG provided in the base 44. Accordingly, the second plate 43PL may slide in the first direction, and in the receiving groove 44RG, the protrusion 43PP may slide in the first direction along the receiving groove 44RG. Because the protrusion 43PP is accommodated in the receiving groove 44RG and slides in the first direction, movement of the second plate 43PL in a width direction may be fixed and the second plate 43PL may move in the first direction.

The third bolt 43B3 may fix the second plate 43PL after the position of the second plate 43PL in the first direction is determined. In an embodiment, the third bolt 43B3 may include a plurality of third bolts 43B3, and the third bolts 43B3 may be arranged at opposite sides of the second plate 43PL in the width direction, e.g., the third direction. In an embodiment, two third bolts 43B3 may be arranged on one side in the width direction, and two third bolts 43B3 may be arranged on an opposite side. However, the disclosure is not limited thereto, and four or more, or four or less third bolts 43B3 may be arranged.

In an embodiment, the third bolt 43B3 may be disposed to be inserted into the second plate 43PL. At this time, as the third bolt 43B3 is tightened, the third bolt 43B3 may pass through the second plate 43PL and be fastened to the base 44, thereby fixing the second plate 43PL. In detail, the second plate 43PL may define an extension hole 43EH through which the third bolt 43B3 is inserted. The extension hole 43EH may be a hole that extends in the longitudinal direction, e.g., the first direction. Accordingly, even when the second plate 43PL may move in the first direction on the base 44, the third bolt 43B3 and the extension hole 43EH may not interfere with each other. In other words, even when the second plate 43PL moves in the first direction, the third bolt 43B3 may be disposed in the extension hole 43EH. In this case, after the second plate 43PL moves and its position is determined, the third bolt 43B3 may be tightened to fix the second plate 43PL to the base 44.

The position measurement unit 43LC may ensure that the position adjustment unit 43 is precisely disposed. In an embodiment, the position measurement unit 43LC may include a micrometer caliper. The position measurement unit 43LC may be used to precisely measure the amount of movement of the second plate 43PL in the first direction, and may allow the position adjustment unit 43 to be disposed at a desired position. The position measurement unit 43LC may include at least one position measurement unit 43LC, and the at least one position measurement unit 43LC may be disposed on one side of the second plate 43PL in the longitudinal direction, e.g., at the rear of the second plate 43PL. In an embodiment, the position measurement unit 43LC may include two position measurement units 43LC which may be respectively arranged on one side and an opposite side of the second plate 43PL in the width direction at the rear of the second plate 43PL, for example.

The base 44 may be disposed under the position adjustment unit 43, e.g., the second plate 43PL, to support the position adjustment unit 43. The base 44 may be larger than the second plate 43PL in a plan view. In an embodiment, the base 44 may have a quadrangular shape, but the disclosure is not limited thereto. In another embodiment, the base 44 may have a circular shape or another polygonal shape. Hereinafter, a case where the base 44 has a quadrangular shape is mainly described.

As described above, the base 44 may define, in a top surface thereof, the receiving groove 44RG which is concave. The receiving groove 44RG may extend in the longitudinal direction, e.g., the first direction (x direction) from the top surface of the base 44 along the center of its width, e.g., a center of the length in the third direction (y direction). The receiving groove 44RG may accommodate the protrusion 43PP. Accordingly, the second plate 43PL may slide in the first direction on the base 44.

In addition, the base 44 may be fixed to the support plate 10. A fourth bolt 44B4 may be inserted into the base 44 and fastened to the support plate 10, and may fix the base 44.

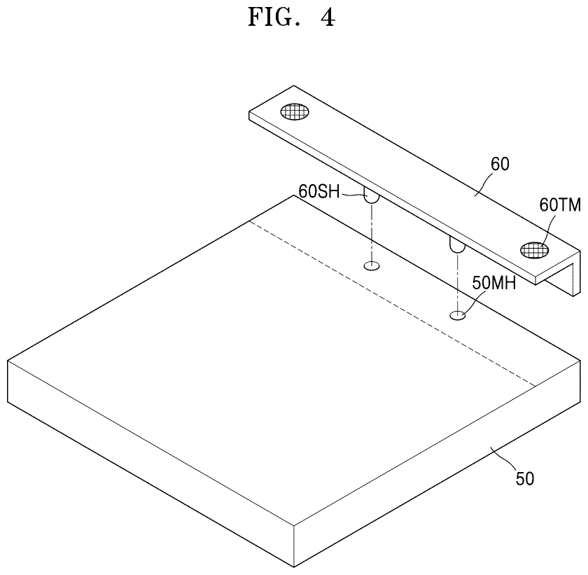

FIG. 4 is a perspective view schematically showing an embodiment of a stage.

Referring to FIG. 4, as described above, a display substrate (not shown) may be disposed (e.g., seated) on the stage 50. In addition, the output laser beam from the optical path module 40 may be irradiated toward the stage 50. At this time, in an embodiment, a target plate 60 may be disposed on one side of the stage 50. The target plate 60 may be disposed at one edge of the stage 50 to cover a portion of a top surface of the stage 50. In an embodiment, the target plate 60 may be formed as a plate that is bent to cover a portion of the top surface of the stage 50 and a neighboring (adjacent) side surface of the stage 50.

In addition, in an embodiment, the target plate 60 may be detachably disposed (e.g., mounted) on the stage 50. In detail, the target plate 60 may include a protruding shaft 60SH that protrudes downward. At this time, the stage 50 may define a mounting hole 50MH into which the protruding shaft 60SH is inserted and fitted. The protruding shaft 60SH and the mounting hole 50MH corresponding to the protruding shaft 60SH may include a plurality of protruding shafts 60SH and a plurality of mounting holes 50MH, respectively.

The output laser beam from the optical path module 40 may be irradiated to the target plate 60. In an embodiment, a target mark 60TM may be provided on a top surface of the target plate 60. In an embodiment, the target mark 60TM may include grid lines. The grid lines have predetermined intervals, e.g., in mm units, and may be used as graduations. Accordingly, an output position of a laser beam may be marked on the target mark 60TM, and precise control of the output position of the laser beam may be facilitated. In the drawing, it is shown that two target marks 60TM are respectively provided at opposite sides of the target plate 60, but the disclosure is not limited thereto. In an embodiment, one target mark 60TM or at least two target marks 60TM may be provided, for example.

As described above, the target plate 60 may be temporarily coupled to the stage 50 and, after being used for marking and adjusting the output laser beam from the optical path module 40, may be detached therefrom. Next, after the display substrate DS is disposed (e.g., seated) on the stage 50, the display substrate DS may be repaired using a laser beam.

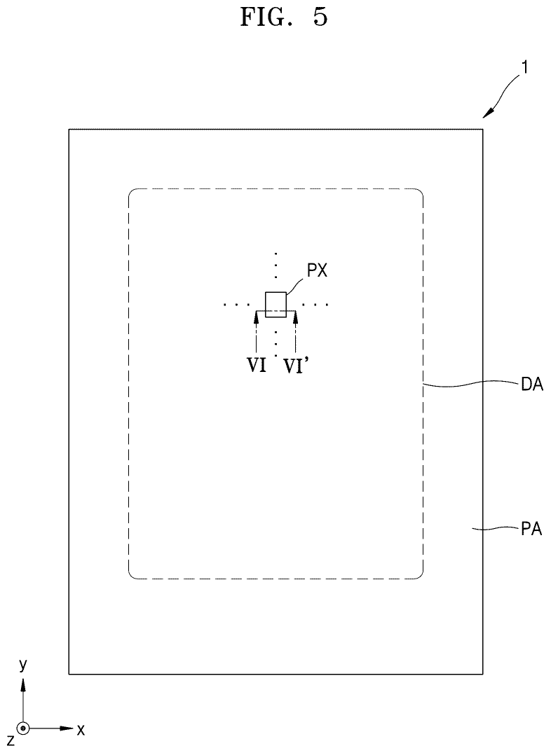

FIG. 5 is a plan view schematically showing an embodiment of a display apparatus manufactured using an apparatus for manufacturing a display apparatus.

Referring to FIG. 5, a display apparatus 1 manufactured in an embodiment may include a display area DA and a peripheral area PA arranged outside the display area DA. The display apparatus 1 may provide an image through an array of a plurality of pixels PX two-dimensionally arranged in the display area DA.

The peripheral area PA is an area that does not provide an image, and may entirely or partially surround the display area DA. A driver or the like for providing an electrical signal or power to a pixel circuit corresponding to each of the pixels PX may be arranged in the peripheral area PA. A pad that is an area to which an electronic device, a printed circuit board, or the like may be electrically connected may be disposed in the peripheral area PA.

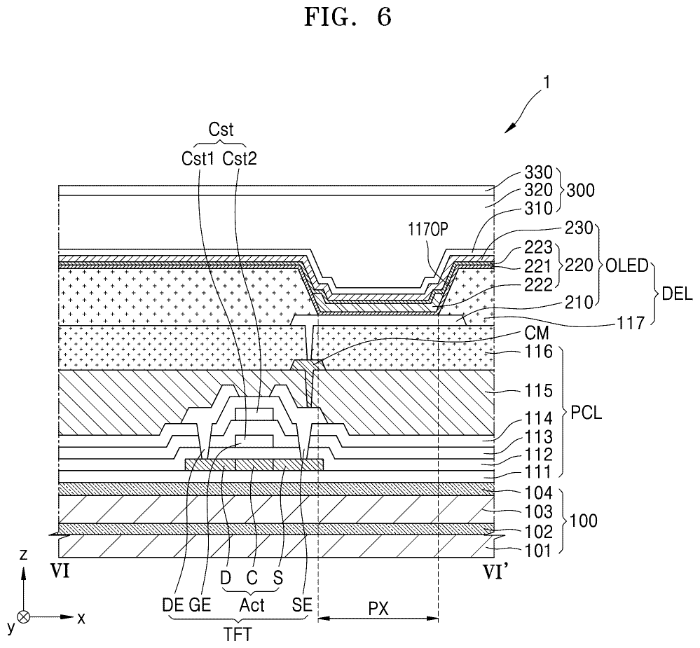

Hereinafter, although the display apparatus 1 is described as including an organic light-emitting diode (refer to OLED in FIG. 6) as a light-emitting element, the display apparatus 1 of the disclosure is not limited thereto. In another embodiment, the display apparatus 1 may include a light-emitting display including an inorganic light-emitting diode, that is, an inorganic light-emitting display. The inorganic light-emitting diode may include a PN diode including materials based on an inorganic material semiconductor. When a voltage is applied to a PN junction diode in a forward direction, holes and electrons are injected, and energy generated due to recombination of the holes and the electrons is converted to light energy to emit light of a predetermined color. The inorganic light-emitting diode described above may have a width of tens to hundreds of micrometers, and in some embodiments, the inorganic light-emitting diode may be also referred to as a micro light-emitting diode (“LED”). In another embodiment, the display apparatus 1 may include a quantum-dot light-emitting display.

The display apparatus 1 may be used as a display screen of various products, e.g., not only portable electronic devices, such as mobile phones, smartphones, tablet personal computers (“PCs”), mobile communication terminals, electronic organizers, electronic books, portable multimedia players (“PMPs”), navigation devices, ultra mobile PCs (“UMPCs”), or the like, but also televisions, laptops, monitors, billboards, Internet of things (“IoT”) devices, or the like. In addition, the display apparatus 1 in an embodiment may be used in wearable devices, such as smart watches, watch phones, glasses-type displays, head mounted displays (“HMDs”), or the like. Furthermore, the display apparatus 1 in an embodiment may be used as an instrument panel of vehicles, a center information display (“CID”) disposed on the center fascia or dashboard of vehicles, a room mirror display in place of side-view mirrors of vehicles, or a display screen disposed at the rear side of a front seat as an entertainment for a rear seat of vehicles.

FIG. 6 is a cross-sectional view schematically showing a display apparatus manufactured using an apparatus for manufacturing a display apparatus in an embodiment, and may correspond to a cross-section of the display apparatus taken along line VI-VI′ of FIG. 5.

Referring to FIG. 6, the display apparatus 1 may include a stack structure of a substrate 100, a pixel circuit layer PCL, a display element layer DEL, and an encapsulation layer 300. The display substrate DS (refer to FIG. 1) may be obtained by stacking at least one of the pixel circuit layer PCL, the display element layer DEL, and the encapsulation layer 300 on, e.g., the substrate 100 that is in a process of manufacturing the display apparatus 1.

The substrate 100 may having a multilayer structure including a base layer including polymer resin and an inorganic layer. In an embodiment, the substrate 100 may include a base layer including polymer resin and a barrier layer that is an inorganic insulating layer, for example. In an embodiment, the substrate 100 may include a first base layer 101, a first barrier layer 102, a second base layer 103, and a second barrier layer 104, which are sequentially stacked, for example. The first base layer 101 and the second base layer 103 may include polyimide (“PI”), polyethersulfone (“PES”), polyarylate, polyetherimide (“PEI”), polyethylene naphthalate (“PEN”), polyethylene terephthalate (“PET”), polyphenylene sulfide (“PPS”), polycarbonate (“PC”), cellulose triacetate (“TAC”), or/and cellulose acetate propionate (“CAP”). The first barrier layer 102 and the second barrier layer 104 may include an inorganic insulating material, such as silicon oxide, silicon oxynitride, and/or silicon nitride. The substrate 100 may have flexibility.

The pixel circuit layer PCL is disposed on the substrate 100. FIG. 6 illustrates that the pixel circuit layer PCL includes a thin-film transistor TFT, and a buffer layer 111, a first gate insulating layer 112, a second gate insulating layer 113, an inter-insulating layer 114, a first planarization insulating layer 115, and a second planarization insulating layer 116, which are arranged under or/and above constituent elements of the thin-film transistor TFT.

The buffer layer 111 may reduce or block infiltration of foreign substances, such as moisture or external air, from under the substrate 100, and may provide a flat surface on the substrate 100. The buffer layer 111 may include an inorganic insulating material, such as silicon oxide, silicon oxynitride, or silicon nitride, and may have a single layer or multilayer structure, each including the above-described material.

The thin-film transistor TFT on the buffer layer 111 may include a semiconductor layer Act, and the semiconductor layer Act may include polysilicon. In an alternative embodiment, the semiconductor layer Act may include amorphous silicon, an oxide semiconductor, or an organic semiconductor. The semiconductor layer Act may include a channel region C, a drain region D, and a source region S, and the drain region D and the source region S are respectively arranged at opposite sides of the channel region C A gate electrode GE may overlap the channel region C.

The gate electrode GE may include a low-resistance metal material. The gate electrode GE may include a conductive material including molybdenum (Mo), aluminum (Al), copper (Cu), titanium (Ti), etc., and may be formed as a multilayer or single layer, each including the above material.

The first gate insulating layer 112 between the semiconductor layer Act and the gate electrode GE may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). Zinc oxide (ZnOₓ) may include zinc oxide (ZnO) and/or zinc peroxide (ZnO₂).

The second gate insulating layer 113 may be provided to cover the gate electrode GE. The second gate insulating layer 113, similar to the first gate insulating layer 112, may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). Zinc oxide (ZnOₓ) may include zinc oxide (ZnO) and/or zinc peroxide (ZnO₂).

An upper electrode Cst2 of a storage capacitor Cst may be disposed above the second gate insulating layer 113. The upper electrode Cst2 may overlap the gate electrode GE thereunder. At this time, the gate electrode GE and the upper electrode Cst2 overlapping each other with the second gate insulating layer 113 therebetween may form the storage capacitor Cst. In other words, the gate electrode GE may function as a lower electrode Cst1 of the storage capacitor Cst.

As such, the storage capacitor Cst and the thin-film transistor TFT may overlap each other. In some embodiments, the storage capacitor Cst may not overlap the thin-film transistor TFT.

The upper electrode Cst2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may be a single layer or multilayer, each including the above-described material.

The inter-insulating layer 114 may cover the upper electrode Cst2. The inter-insulating layer 114 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). Zinc oxide (ZnOₓ) may include zinc oxide (ZnO) and/or zinc peroxide (ZnO₂). The inter-insulating layer 114 may be a single layer or multilayer, each including the above-described inorganic insulating material.

A drain electrode DE and a source electrode SE may each be arranged on the inter-insulating layer 114. The drain electrode DE and the source electrode SE may be respectively connected to the drain region D and the source region S through a contact hole defined in the insulating layers thereunder. The drain electrode DE and the source electrode SE may include a material with excellent conductivity. The drain electrode DE and the source electrode SE may include a conductive material including molybdenum (Mo), aluminum (Al), copper (Cu), titanium (Ti), etc., and may be formed as a multilayer or single layer, each including the above material. In an embodiment, the drain electrode DE and the source electrode SE may each have a multilayer structure of Ti/Al/Ti.

The first planarization insulating layer 115 may cover the drain electrode DE and the source electrode SE. The first planarization insulating layer 115 may include an organic insulating material, such as a general purpose polymer such as polymethylmethacrylate (“PMMA”) or polystyrene (“PS”), a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, and blends thereof.

The second planarization insulating layer 116 may be disposed on the first planarization insulating layer 115. The second planarization insulating layer 116 may include the same material as that of the first planarization insulating layer 115, and may include an organic insulating material, such as a general purpose polymer such as PMMA or PS, a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, and blends thereof.

The display element layer DEL may be disposed on the pixel circuit layer PCL having the above-described structure. The display element layer DEL may include an organic light-emitting diode OLED as a display element (that is, a light-emitting element), and the organic light-emitting diode OLED may include a stack structure of a pixel electrode 210, an intermediate layer 220, and a common electrode 230. The organic light-emitting diode OLED may emit red light, green light, or blue light, or may emit red light, green light, blue light, or white light, for example. The organic light-emitting diode OLED may emit light through an emission region, and the emission region may be defined as a pixel PX.

The pixel electrode 210 of the organic light-emitting diode OLED may be electrically connected to the thin-film transistor TFT through contact holes defined in the second planarization insulating layer 116 and the first planarization insulating layer 115 and a contact metal CM arranged on the first planarization insulating layer 115.

The pixel electrode 210 may include a conductive oxide, such as indium tin oxide (“ITO”), indium zinc oxide (“IZO”), zinc oxide (ZnO), indium oxide (In₂O₃), indium gallium oxide (“IGO”), or aluminum zinc oxide (“AZO”). In another embodiment, the pixel electrode 210 may include a reflective film including silver (Ag), magnesium (Mg), aluminum (Al), platinum (Pt), palladium (Pd), gold (Au), nickel (Ni), neodymium (Nd), iridium (Ir), chromium (Cr), or compounds thereof. In another embodiment, the pixel electrode 210 may further include a film including ITO, IZO, ZnO, or In₂O₃ above/under the above-described reflective film.

A pixel-defining film 117 defining an opening 117OP that exposes a central portion of the pixel electrode 210 is disposed on the pixel electrode 210. The pixel-defining film 117 may include an organic insulating material and/or an inorganic insulating material. The opening 117OP may define an emission region of light emitted from the organic light-emitting diode OLED. In an embodiment, the size/width of the opening 117OP may correspond to the size/width of the emission region, for example. Accordingly, the size and/or width of the pixel PX may depend on the size and/or width of the opening 117OP in the corresponding pixel-defining film 117.

The intermediate layer 220 may include an emission layer 222 formed to correspond to the pixel electrode 210. The emission layer 222 may include a polymer or low-molecular-weight organic material that emits light of a predetermined color. In an alternative embodiment, the emission layer 222 may include an inorganic light-emitting material or quantum dots.

In an embodiment, the intermediate layer 220 may include a first functional layer 221 and a second functional layer 223, which are respectively disposed under and above the emission layer 222. The first functional layer 221 may include, e.g., a hole transport layer (“HTL”), or may include a HTL and a hole injection layer (“HIL”). The second functional layer 223 that is disposed above the emission layer 222 may include an electron transport layer (“ETL”) and/or an electron injection layer (“EIL”). The first functional layer 221 and/or the second functional layer 223, like the common electrode 230 described below, may be a common layer that is formed to cover an entirety of the substrate 100.

The common electrode 230 may be disposed on the pixel electrode 210 and may overlap the pixel electrode 210. The common electrode 230 may include a conductive material having a relatively low work function. In an embodiment, the common electrode 230 may include a (semi)transparent layer including silver (Ag), magnesium (Mg), aluminum (Al), platinum (Pt), palladium (Pd), gold (Au), nickel (Ni), neodymium (Nd), iridium (“IR”), chromium (Cr), lithium (Li), calcium (Ca), or alloys thereof, for example. In an alternative embodiment, the common electrode 230 may further include a layer including ITO, IZO, ZnO or In₂O₃ on the (semi-)transparent layer including the above-described material. The common electrode 230 may be unitary to cover an entirety of the substrate 100.

The encapsulation layer 300 may be disposed on the display element layer DEL and may cover the display element layer DEL. The encapsulation layer 300 includes at least one inorganic encapsulation layer and at least one organic encapsulation layer, and in an embodiment, FIG. 6 illustrates that the encapsulation layer 300 includes a first inorganic encapsulation layer 310, an organic encapsulation layer 320, and a second inorganic encapsulation layer 330, which are sequentially stacked.

The first inorganic encapsulation layer 310 and the second inorganic encapsulation layer 330 may include one or more inorganic materials among aluminum oxide, titanium oxide, tantalum oxide, hafnium oxide, zinc oxide, silicon oxide, silicon nitride, and silicon oxynitride. The organic encapsulation layer 320 may include a polymer-based material. The polymer-based material may include acrylic resin, epoxy-based resin, polyimide, and polyethylene. In an embodiment, the organic encapsulation layer 320 may include acrylate. The organic encapsulation layer 320 may be formed by curing a monomer or applying a polymer. The organic encapsulation layer 320 may have transparency.

Although not shown, a touch sensor layer may be disposed on the encapsulation layer 300, and an optical functional layer may be disposed on the touch sensor layer. The touch sensor layer may obtain coordinate information according to an external input, e.g., a touch event. The optical functional layer may reduce reflectivity of light (external light) incident on a display apparatus from the outside, and/or may improve the color purity of light emitted from the display apparatus. In an embodiment, the optical functional layer may include a retarder and/or a polarizer. The retarder may be of a film type or a liquid crystal coating type, and may include a λ/2 retarder and/or a λ/4 retarder. The polarizer may also be of a film type or a liquid crystal coating type. The film type may include a stretchable synthetic resin film, and the liquid crystal coating type may include liquid crystals arranged in a predetermined array. The retarder and the polarizer may further include a protective film.

An adhesive member may be disposed between the touch sensor layer and the optical functional layer. The adhesive member may be any adhesive member generally known in the related art without limitation. The adhesive member may be a pressure sensitive adhesive (“PSA”).

By embodiments, it is possible to provide an apparatus and method for manufacturing a display apparatus, and the apparatus may allow precise adjustment of input and output positions of a laser beam, thereby enabling a more efficient repair process.

Effects of the disclosure are not limited to the effects mentioned above, and other effects not mentioned will be clearly understood by those skilled in the art from the description of the claims.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. An apparatus for manufacturing a display apparatus including a display substrate, the apparatus comprising:
a stage on which the display substrate is disposed;
a light source unit which generates light and irradiates a laser beam in a first direction; and
an optical path module which reflects the laser beam irradiated and input from the light source unit, outputs the laser beam in a second direction crossing the first direction, and irradiates the laser beam on the stage, the optical path module comprising:
a head unit defining an input opening through which the laser beam is input;
a level adjustment unit which is disposed under the head unit and adjusts a level of the head unit in a height direction;
a position adjustment unit which is disposed under the level adjustment unit and adjusts a position of the head unit in a longitudinal direction; and
a base disposed under the position adjustment unit.

2. The apparatus of claim 1, wherein the optical path module further comprises a grid plate which covers the input opening in the head unit and comprises grid lines.

3. The apparatus of claim 2, wherein the optical path module further comprises a guide rail disposed on one surface of the head unit and defining a groove so that the grid plate slides and is detachable from the head unit.

4. The apparatus of claim 2, wherein the grid plate comprises an alignment protrusion protruding from a bottom portion of the grid plate, and the alignment protrusion is coupled to an alignment recess provided in the level adjustment unit.

5. The apparatus of claim 1, wherein the level adjustment unit comprises a first plate and first and second bolts inserted into the first plate,
wherein the first bolt is fastened to a threaded hole of the position adjustment unit, and the second bolt is not fastened to the position adjustment unit.

6. The apparatus of claim 5, wherein the first bolt lowers the first plate as the first bolt is tightened, and the second bolt raises the first plate as the second bolt is tightened.

7. The apparatus of claim 5, wherein the second bolt contacts a top surface of the position adjustment unit, wherein the second bolt comprises a rounded end screw.

8. The apparatus of claim 5, wherein the first bolt is disposed further inside the first plate than the second bolt.

9. The apparatus of claim 5, wherein
the level adjustment unit further comprises a horizontal measurement unit which is disposed on the first plate and measures a degree of horizontality of the first plate.

10. The apparatus of claim 9, wherein the horizontal measurement unit is disposed on each edge along a perimeter of the first plate.

11. The apparatus of claim 1, wherein the position adjustment unit comprises: a second plate which is movable in the longitudinal direction; and a third bolt inserted into the second plate, wherein the second plate defines an extension hole through which the third bolt is inserted.

12. The apparatus of claim 11, wherein the extension hole is an opening extending in the longitudinal direction so that the third bolt is disposed in the extension hole when the second plate moves in the longitudinal direction.

13. The apparatus of claim 11, wherein the position adjustment unit further comprises a position measurement unit which is disposed on one side of the second plate in the longitudinal direction and measures a degree of movement of the second plate in the longitudinal direction.

14. The apparatus of claim 11, wherein the position adjustment unit further comprises a protrusion protruding from a bottom portion of the second plate toward the base and extending in the longitudinal direction,
the base defines a receiving groove extending in the longitudinal direction and accommodates the protrusion, and
the protrusion is slidable along the receiving groove.

15. The apparatus of claim 1, further comprising a target plate on one side of the stage, wherein the target plate is detachable and comprises a target mark on a top surface of the target plate and indicates a position where the laser beam output by the optical path module is irradiated.

16. The apparatus of claim 15, wherein the target plate further comprises a protruding shaft protruding from a bottom portion of the target plate, the stage further defines a mounting hole provided at a position corresponding to the protruding shaft, and the protruding shaft is fitted into the mounting hole.

17. The apparatus of claim 1, further comprising an optical unit disposed between the light source unit and the optical path module and comprising a plurality of lenses.

18. The apparatus of claim 1, further comprising a support plate which supports the light source unit and the optical path module and is spaced apart from and faces the stage.

19. A method of manufacturing a display apparatus including a display substrate, the method comprising:
arranging the display substrate on a stage;
irradiating a laser beam in a first direction by generating light from a light source unit; and
repairing the display substrate by reflecting, by an optical path module, the laser beam irradiated and input from the light source unit, outputting by the optical path module, the laser beam in a second direction crossing the first direction, and irradiating, by the optical path module, the laser beam on the display substrate,
wherein the optical path module comprises:
a head unit defining an input opening through which the laser beam is input;
a level adjustment unit which is disposed under the head unit and adjusts a level of the head unit in a height direction;
a position adjustment unit which is disposed under the level adjustment unit and adjusts a position of the head unit in a longitudinal direction; and
a base disposed under the position adjustment unit.

20. A method of manufacturing an electronic device including a display substrate, the method comprising:
arranging the display substrate on a stage;
irradiating a laser beam in a first direction by generating light from a light source unit; and
repairing the display substrate by reflecting, by an optical path module, the laser beam irradiated and input from the light source unit, outputting by the optical path module, the laser beam in a second direction crossing the first direction, and irradiating, by the optical path module, the laser beam on the display substrate,
wherein the optical path module comprises:
a head unit defining an input opening through which the laser beam is input;
a level adjustment unit which is disposed under the head unit and adjusts a level of the head unit in a height direction;
a position adjustment unit which is disposed under the level adjustment unit and adjusts a position of the head unit in a longitudinal direction; and
a base disposed under the position adjustment unit.
